(19) United States
(12) Patent Application Publication
(10) Pub. No.: US 2026/0198127 A1
(43) Pub. Date: Jul. 9, 2026

(54) VERTICAL CHARGE TRANSFER PHOTOELECTRIC SENSOR, MANUFACTURING METHOD THEREFOR AND OPERATION METHOD THEREFOR

(71) Applicant: WUHAN XINXIN SEMICONDUCTOR MANUFACTURING CO., LTD., Wuhan, Hubei (CN)

(72) Inventors: Kaiwei CAO, Wuhan, Hubei (CN); Peng SUN, Wuhan, Hubei (CN); Jun ZHOU, Wuhan, Hubei (CN)

(21) Appl. No.: 19/130,642

(22) PCT Filed: Dec. 8, 2023
(86) PCT No.: PCT/CN2023/137324

§ 371 Date: May 16, 2025

(30) Foreign Application Priority Data
Feb. 14, 2023 (CN) 202310130394.1

(51) Int. Cl. H10F 39/00

(52) U.S. Cl. CPC H10F 39/812; H10F 39/014; H10F 39/80373; H10F 39/807

(57) ABSTRACT

The present invention relates to a vertically-charge-transferring pixel sensor (VPS) and methods of manufacture and operation thereof. In the VPS, deep trench isolation (DTI) structures and shallow trench isolation (STI) structures in a substrate contain deep trench electrodes and shallow trench electrodes, respectively. In a light sensing operation, a positive bias voltage can be applied between the substrate and the deep and shallow trench electrodes to raise a potential barrier at boundaries of the DTI and STI structures and the substrate. This reduces the likelihood of photoelectrons being captured at the boundaries, thus reducing loss of photoelectrons and contributing to enhanced quantum efficiency. In addition, in the STI structures, the shallow trench electrodes may be offset toward light sensing regions beside the STI structures. In this way, a voltage applied to the shallow trench electrodes has a greater impact on potentials in the light sensing regions than on potentials in charge readout regions, thus additionally reducing loss of photoelectrons and minimizing the influence on MOS transistors in the charge readout regions.

### TECHNICAL FIELD

The present invention relates to the field of light sensing technology and, in particular, to a vertically-charge-transferring pixel sensor (VPS) and methods of manufacture and operation thereof.

### BACKGROUND

Conventional optoelectronic sensors include CCD and CMOS sensors. Compared with CCD ones, CMOS sensors have found wider use in recent years thanks to higher image capture capabilities, higher resolution, lower power consumption and compatibility with CMOS processes. However, CMOS sensors are also associated with a number of disadvantages. For example, each pixel in a CMOS sensor includes a photodiode and multiple transistors for charge transfer and readout. This makes it increasingly difficult to increase the pixel fill factor.

There has been proposed a vertically-charge-transferring pixel sensor (VPS), for example, in Chinese Pat. App. Pub. Nos. CN102938409A and CN107658321A, in which each pixel includes a conductively doped substrate and a stack on a surface of the substrate. The stack includes a gate dielectric layer, a floating gate (FG), an inter-gate dielectric layer and a control gate (CG). The substrate has a light sensing region and a charge readout region isolated from the light sensing region. The stack in the light sensing region constitutes a MOS capacitor together with the substrate, and the stack in the charge readout region forms a gate structure of a MOS transistor. Source and drain regions of the MOS transistor are formed in the charge readout region on opposite sides of the gate structure. In order to sense light, an appropriate voltage is applied to the MOS capacitor to form a depletion region in the substrate. When light is incident on the substrate, photons enter the depletion region and excite electrons therein into photoelectrons, which are then driven by a vertical electric field to gather at the substrate surface in the light sensing region. Under the action of charge coupling, a potential change is caused in the FG co-shared by the MOS capacitor and the MOS transistor, which in turn causes a change in the threshold voltage of the MOS transistor. Moreover, the more photoelectrons gather at the substrate surface in the light sensing region, the greater the threshold voltage change is. Therefore, the photoelectrons can be read out by detecting the threshold voltage change, or a change of another parameter of the transistor that it causes. The photoelectron count is then converted into a gray-scale value of the pixel, enabling the formation of an image. Compared with conventional CCD and CMOS sensors, through using the MOS capacitors and the MOS transistors for light sensing and photoelectron readout, the VPS has a straightforward pixel layout with a greatly increased pixel fill factor, which makes it much competitive in pixel miniaturization. Multiple pixels in the VPS may be arranged into an array, in which the CGs of the pixels may be connected to form multiple word lines, and their drain regions may be connected to form multiple bit lines. In this way, any specified pixel can be addressed and operated, providing ease of operation.

A challenge to miniaturization of pixels in the VPS is how to avoid crosstalk in the substrate between adjacent pixels. To overcome this, it has been proposed to form deep trench isolation (DTI) structures in the substrate between pixel areas and typically a shallow trench isolation (STI) structure between the light sensing region and the charge readout region in each pixel area. However, as there tend to be many defects at boundaries between the DTI and STI structures and the substrate, some photoelectrons may be captured by the defects during light sensing of the pixels, leading to low quantum efficiency. What is worse is that the captured photoelectrons may cause dark current, and hence white pixel artifacts and heavy background noise, which are detrimental to imaging quality of the sensor.

### SUMMARY

The present invention provides a vertically-charge-transferring pixel sensor (VPS) with capabilities of suppressing capture of photoelectrons at boundaries between trench isolation structures and a substrate therein and with improved performance. Also provided are methods of manufacture and operation of the VPS.

In one aspect, the present invention provides a VPS including: a substrate of a first doping type; deep trench isolation (DTI) structures each including a deep trench extending through the substrate, a deep trench electrode formed in the deep trench and a DTI dielectric material filled in the deep trench so as to isolate the deep trench electrode from the substrate, the DTI structures partitioning the substrate into a plurality of pixel areas; shallow trench isolation (STI) structures each including a shallow trench extending from a surface of the substrate into the substrate, a shallow trench electrode formed in the shallow trench and an STI dielectric material filled in the shallow trench so as to isolate the shallow trench electrode from the substrate, the STI structures traversing the respective pixel areas and thereby partitioning them into light sensing regions and charge readout regions on its opposite sides thereof; gate structures formed on surfaces of the respective pixel areas so as to extend from the respective light sensing regions to the respective charge readout regions, the gate structures in the light sensing regions constituting, together with the substrate, MOS capacitors for collecting photo-charge; and source and drain regions formed in the charge readout regions on opposite sides of the gate structures so as to constitute, together with the gate structures in the charge readout regions, MOS transistors for readout of the photo-charge.

In another aspect, the present invention provides a method of manufacture of a VPS, which includes: providing a substrate of a first doping type; forming deep and shallow trenches extending from one side of the substrate into the substrate; forming DTI and STI structures in the substrate, each of the DTI structures including a respective one of the deep trenches, a deep trench electrode formed in the deep trench and a DTI dielectric material filled in the deep trench so as to isolate the deep trench electrode from the substrate, the DTI structures partitioning the substrate into a plurality of pixel areas, each of the STI structures including a respective one of the shallow trenches, a shallow trench electrode formed in the shallow trench and an STI dielectric material filled in the shallow trench so as to isolate the shallow trench electrode from the substrate, the STI structures traversing the respective pixel areas and thereby partitioning them into light sensing regions and charge readout regions on its opposite sides thereof; and forming gate structures on surfaces of the respective pixel areas and source and drain regions in the charge readout regions on opposite sides of the gate structures, the gate structures extending from the respective light sensing regions to the respective charge readout regions, the gate structures in the light sensing regions constituting, together with the substrate, MOS capacitors for collecting photo-charge, the gate structures in the charge readout regions constituting, together with the source and drain regions, MOS transistors for readout of the photo-charge.

In yet another aspect, the present invention provides a method of operation of the VPS as defined above, which includes a light sensing operation and a photoelectron readout operation. In the light sensing operation, a positive voltage is applied to the gate structures, a first negative voltage to the substrate and a second negative voltage lower than the first negative voltage to the deep and shallow trench electrodes, causing photoelectrons to gather at top surfaces of the light sensing regions. In the photoelectron readout operation, with the first and second negative voltages being maintained and corresponding voltages being applied respectively to the gate structures, the source regions and the drain regions, threshold voltage changes of the MOS transistors before and after the light sensing operation are detected for readout of the photoelectrons.

In the VPS and the method of manufacture thereof, the deep and shallow trench electrodes in the DTI and STI structures in the substrate serve for generation of electric fields at boundaries of the trench isolation structures and the substrate. In a light sensing operation, a positive bias voltage can be applied between the deep and shallow trench electrodes and the substrate to raise a potential barrier at the boundaries of the DTI and STI structures and the substrate. This reduces the likelihood of photoelectrons being captured at the boundaries, thus reducing loss of photoelectrons and contributing to enhanced quantum efficiency and improved imaging quality.

Further, in the STI structures, the shallow trench electrodes may be offset toward light sensing regions beside the STI structures. In this way, a voltage applied to the shallow trench electrodes has a greater impact on potentials in the light sensing regions than on potentials in the charge readout regions, thus additionally reducing loss of photoelectrons and minimizing the influence on the MOS transistors in the charge readout regions.

The light sensing and photoelectron readout operations in the method of operation can provide optoelectronic sensing. Through applying the first negative voltage to the substrate and the second negative voltage that is lower than the first negative voltage to the deep and shallow trench electrodes, a negative bias voltage is present between the deep and shallow trench electrodes and the substrate, which raises the potential barrier at the boundaries of the DTI and STI structures and the substrate, reducing the likelihood of photoelectrons being captured at the boundaries and contributing to improved imaging quality. The method may also include a reset operation, in which through applying first reset voltage to the substrate and a second reset voltage higher than the first reset voltage to the deep and shallow trench electrodes, a positive bias voltage is present between the deep and shallow trench electrodes and the substrate, facilitating release of electrons trapped at the boundaries and reducing background noise in subsequent light sensing and photoelectron readout operations.

### BRIEF DESCRIPTION OF THE DRAWINGS

FIG. 1 is a schematic cross-sectional view of a vertically-charge-transferring pixel sensor (VPS).

FIG. 2 is a schematic cross-sectional view of a VPS according to an embodiment of the present invention.

FIG. 3 is a schematic plan view of a substrate according to an embodiment of the present invention.

FIG. 4 is a schematic plan view of a substrate according to an alternative embodiment of the present invention.

FIG. 5a is a schematic cross-sectional view of a structure resulting from forming deep trenches in a substrate in a method of manufacture of a VPS according to an embodiment of the present invention.

FIG. 5b is a schematic plan view of a structure resulting from forming deep trenches in a substrate in a method of manufacture of a VPS according to an embodiment of the present invention.

FIG. 6 is a schematic cross-sectional view of a structure resulting from forming a first photoresist layer on a substrate in a method of manufacture of a VPS according to an embodiment of the present invention.

FIG. 7 is a schematic cross-sectional view of a structure resulting from forming shallow trenches in a substrate in a method of manufacture of a VPS according to an embodiment of the present invention.

FIG. 8 is a schematic cross-sectional view of a structure resulting from removing a sacrificial layer in a method of manufacture of a VPS according to an embodiment of the present invention.

FIG. 9a is a schematic cross-sectional view of a structure resulting from forming a trench electrode layer in a method of manufacture of a VPS according to an embodiment of the present invention.

FIG. 9b is a schematic plan view of a substrate after forming a trench electrode layer in a method of manufacture of a VPS according to an embodiment of the present invention.

FIG. 10a is a schematic cross-sectional view of a structure resulting from forming a second photoresist layer on a substrate in a method of manufacture of a VPS according to an embodiment of the present invention.

FIG. 10b is a schematic plan view of a substrate and a second photoresist layer in a method of manufacture of a VPS according to an embodiment of the present invention.

FIG. 11a is a schematic cross-sectional view of a structure resulting from forming first gaps in deep and shallow trenches in a method of manufacture of a VPS according to an embodiment of the present invention.

FIG. 11b is a schematic cross-sectional view of a structure resulting from forming first gaps in deep and shallow trenches in a method of manufacture of a VPS according to an alternative embodiment of the present invention.

FIG. 12 is a schematic cross-sectional view of a structure resulting from forming a first dielectric filler layer in a method of manufacture of a VPS according to an alternative embodiment of the present invention.

FIG. 13 is a schematic cross-sectional view of a structure resulting from planarizing a top surface of a first dielectric filler layer in a method of manufacture of a VPS according to an alternative embodiment of the present invention.

FIG. 14 is a schematic cross-sectional view of a structure resulting from forming deep trench electrodes and shallow trench electrodes by again etching back a trench electrode layer in a method of manufacture of a VPS according to an alternative embodiment of the present invention.

FIG. 15 is a schematic cross-sectional view of a structure resulting from forming a second dielectric filler layer in a method of manufacture of a VPS according to an alternative embodiment of the present invention.

FIG. 16 is a schematic cross-sectional view of a structure resulting from removing a hard mask layer and part of an STI dielectric material in a method of manufacture of a VPS according to an alternative embodiment of the present invention.

FIG. 17 is a schematic cross-sectional view of a structure resulting from forming a gate dielectric layer and a floating gate material layer in a method of manufacture of a VPS according to an alternative embodiment of the present invention.

FIG. 18 is a schematic cross-sectional view of a structure resulting from removing part of a DTI dielectric material and forming an inter-gate dielectric layer and a control gate material layer in a method of manufacture of a VPS according to an alternative embodiment of the present invention.

FIG. 19 is a schematic cross-sectional view of a structure resulting from a control gate material layer in a method of manufacture of a VPS according to an alternative embodiment of the present invention.

### DETAILED DESCRIPTION

Vertically-charge-transferring pixel sensors (VPS's) and methods of manufacture and operation thereof according to the present invention will be described in greater detail below with reference to the accompanying drawings, which illustrate specific embodiments thereof. From the following description, advantages and features of the present invention will be more apparent. Note that the figures are provided in a very simplified form not necessarily drawn to exact scale for the only purpose of helping explain the disclosed embodiments in a more convenient and clearer way. Embodiments of the present invention should not be construed as limited to the particular shapes of regions illustrated herein but are to include deviations in shapes that result, for example, from manufacturing.

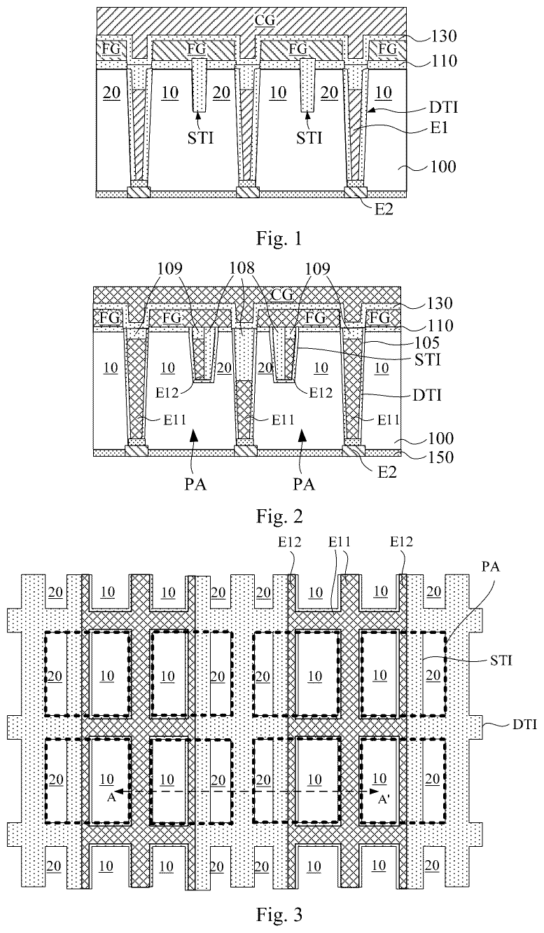

FIG. 1 is a schematic cross-sectional view of a VPS. FIG. 1 only shows a part of the VPS. Referring to FIG. 1, the VPS may include a plurality of pixels, each pixel includes a portion of a substrate 100 and a stack formed on one side of the substrate 100. The stack includes a gate dielectric layer 110, a floating gate FG, an inter-gate dielectric layer 130 and a control gate CG. The portion of the substrate 100 in the pixel is a pixel area including a light sensing region 10 and a charge readout region 20, which are isolated from each other by a shallow trench isolation (STI) structure STI. The light sensing region 10 constitutes, together with the overlying stack, a MOS capacitor for collecting photoelectrons in a light sensing operation. A MOS transistor is formed in the charge readout region 20, which includes a gate structure formed by a portion of the stack residing on the charge readout region 20 and source and drain regions formed in the charge readout region 20 (on front and rear sides of the gate structure, respectively, as viewed in the orientation of FIG. 1). Substrate electrodes E2 may be formed on the other side of the substrate 100, and a voltage can be applied to the substrate 100 in the pixel areas through the substrate electrodes E2.

In the VPS of FIG. 1, the pixel areas of the substrate 100 may be defined by deep trench isolation (DTI) structures DTI, which may extend through the substrate 100. Each DTI structure DTI includes a deep trench extending through the substrate 100, a trench electrode E1 formed in the deep trench and a DTI dielectric material filled in the deep trench so as to isolate the trench electrode E1 from the substrate 100. The trench electrode E1 may extend into a non-pixel area of the substrate 100, such as a peripheral circuit area, to allow a voltage to be applied thereto. During operation of the VPS, an appropriate voltage may be applied to the trench electrodes E1 to improve performance of the sensor. For example, in a light sensing operation, a positive bias voltage may be applied between the substrate 100 and the trench electrodes E1 to lower the risk of photoelectrons being captured by voids and defects at boundaries of the DTI structures DTI and the substrate 100 and reduce leakage currents in the sensor.

The VPS of FIG. 1 needs further improvement. In detail, in a light sensing operation, photoelectrons collected at the surface of the substrate 100 in the light sensing regions 10 are subjected to optoelectronic detection. However, since the STI structures STI surrounding the light sensing regions 10 is generally filled with a dielectric material, there remains a large risk of the photoelectrons being captured at boundaries of the STI structures STI and the light sensing regions 10 after they enter the light sensing regions 10. In addition, in a photoelectron readout operation, with the same voltage as in a light sensing operation being applied to the substrate 100 and the trench electrodes E1, threshold voltage changes of the MOS transistors are detected. Since well regions of the MOS transistors are formed in the charge readout regions 20, the trench electrodes E1 in the DTI structures DTI surrounding the charge readout regions 20 must not extend over the charge readout regions 20 in a thickness direction of the substrate 100, in order to avoid the trench electrodes E1 from adversely affecting potentials in the well regions of the MOS transistors. To this end, the trench electrodes E1 in the DTI structures DTI surrounding the pixel areas all span lower portions of the DTI structures DTI, which are of substantially the same height, and the remaining upper portions of the DTI structures DTI are typically filled with a dielectric material. Consequently, when photoelectrons enter the light sensing regions 10 surrounded by the upper portions of the DTI structures DTI, there is still a large risk of them being captured at boundaries of the DTI structures DTI and the light sensing regions 10.

As detailed blow, compared with the VPS of FIG. 1, VPS's described in the following embodiments are at least associated with a reduced risk of photoelectrons being captured at the boundaries of the STI structures STI and the light sensing regions.

FIG. 2 is a schematic cross-sectional view of a VPS according to an embodiment of the present invention. FIG. 2 only shows a part of the VPS. Referring to FIG. 2, the VPS includes:
a substrate 100 of a first doping type;
deep trench isolation (DTI) structures DTI each including a deep trench extending through the substrate 100, a deep trench electrode E11 formed in the deep trench and a DTI dielectric material filled in the deep trench so as to isolate the deep trench electrode E11 from the substrate 100, the DTI structures DTI partitioning the substrate 100 into a plurality of pixel areas PA;
shallow trench isolation (STI) structures STI each including a shallow trench extending from a surface of the substrate 100 into the substrate 100, a shallow trench electrode E12 formed in the shallow trench and an STI dielectric material filled in the shallow trench so as to isolate the shallow trench electrode E12 from the substrate 100, each STI structure STI traversing the corresponding pixel area PA and thereby partitioning the STI structure into a light sensing region 10 and a charge readout region 20 on its opposite sides of the STI structure;
gate structures formed on surfaces of the respective pixel areas PA so as to extend from the respective light sensing regions 10 to the respective charge readout regions 20, the gate structures in the light sensing regions 10 constituting, together with the substrate, MOS capacitors for collecting photo-charge; and
source and drain regions formed in the charge readout regions 20 on opposite sides of the gate structures so as to constitute, together with the gate structures in the charge readout regions 20, MOS transistors for readout of the photo-charge.

The semiconductor substrate 100 may be any of various suitable semiconductor substrates known in the art, and may be made of a material including silicon, germanium, silicon germanium, silicon carbide, gallium arsenide, gallium phosphide, indium phosphide, indium arsenide, indium antimonide or the like. In this embodiment, the substrate 100 is of the first doping type, which enables the formation of depletion regions in a light sensing operation. For example, the first doping type is p-type. For example, the substrate 100 is a silicon substrate doped with boron or boron difluoride.

Each gate structure may include a stack on the surface of the respective pixel area PA, which consists of a gate dielectric layer 110, a floating gate FG, an inter-gate dielectric layer 130 and a control gate CG, and spacers on sidewalls of the floating gate FG, the inter-gate dielectric layer 130 and the control gate CG. The source and drain regions may be formed on front and rear sides of the respective gate structures, respectively, as viewed in the orientation of FIG. 2. The charge readout regions 20 may further include well regions (not shown). In operation of the VPS, light enters the pixels from the other side of the substrate 100 (e.g., the side on which substrate electrodes E2 are formed), producing photoelectrons. Under the action of an appropriate bias voltage, the photoelectrons move toward the gate structures and gather at top surfaces of the light sensing regions 10, causing potential changes in the floating gates FG that are co-shared by the MOS capacitors and the MOS transistors. The potential changes in the floating gates FG in turn cause threshold voltage changes of the MOS transistors, which can be detected for optoelectronic processing and imaging.

According to embodiments of the present invention, the light sensing regions 10 and the charge readout regions 20 are located on opposite sides of the STI structures STI. Optionally, in STI, the shallow trench electrodes E12 may be offset toward the light sensing regions 10 on one side of the STI structures STI. In other words, the STI dielectric material between the shallow trench electrodes E12 and the light sensing regions 10 on one side of the STI structures STI may have an average thickness less than an average thickness of the STI dielectric material between the shallow trench electrodes E12 and the charge readout regions 20 on the other side of the STI structures STI. In this way, a voltage applied to the shallow trench electrodes E12 will have a greater impact on potentials in the light sensing regions 10 than on potentials in the charge readout regions 20. This helps reduce loss of photoelectrons in the light sensing regions 10 while not considerably affecting the MOS transistors in the charge readout regions 20.

As shown in FIG. 2, the VPS includes a linear isolation layer 105, a first dielectric filler layer 108 and a second dielectric filler layer 109, which provide the DTI and STI dielectric materials.

Specifically, the linear isolation layer 105 lines inner surfaces of the deep and shallow trenches. The deep trench electrodes E11 are formed on surface portions of the linear isolation layer 105 in the deep trenches. The shallow trench electrodes E12 are formed on surface portions of the linear isolation layer 105 in the shallow trenches.

The first dielectric filler layer 108 resides on the remaining surface portions of the linear isolation layer 105 in the deep trenches and is contiguous with the deep trench electrodes E11. The first dielectric filler layer 108 also resides on the remaining surface portions of the linear isolation layer 105 in the shallow trenches and is contiguous with the shallow trench electrodes E12. The stack of the first dielectric filler layer 108 and the linear isolation layer 105 laterally surrounds the charge readout regions 20 and isolates the charge readout regions 20 from the deep trench electrodes E11 and the shallow trench electrodes E12.

The second dielectric filler layer 109 resides on top surfaces of the shallow trench electrodes E12 and the deep trench electrodes E11.

For example, the linear isolation layer 105 may have a thickness of 5 nm to 20 nm, and the first dielectric filler layer 108 may have a thickness of 10 nm to 50 nm. The deep trench electrodes E11 and the shallow trench electrodes E12 may each include one, or a combination of two or more, of tungsten, tungsten silicide, titanium, titanium nitride and doped polysilicon.

In each shallow trench, the shallow trench electrode E12 and the first dielectric filler layer 108 are juxtaposed in a widthwise direction of the shallow trench over at least part of a depth thereof. Referring to FIG. 2, in one embodiment, in each STI structure STI, the shallow trench electrode E12 extends along a side surface thereof adjacent to the light sensing region 10. Moreover, for example, part of the linear isolation layer 105 on a bottom surface of the shallow trench is covered by the shallow trench electrode E12, and the rest is covered by the first dielectric filler layer 108. In this way, a side surface of the shallow trench electrode E12 facing the charge readout region 20 is entirely covered by the first dielectric filler layer 108. That is, the shallow trench electrode E12 is isolated from the charge readout region 20 by the entire stack of the first dielectric filler layer 108 and the linear isolation layer 105. With this arrangement, because of a large thickness of the STI dielectric material between the shallow trench electrode E12 and the charge readout region 20, a voltage applied to the shallow trench electrode E12 will have a minimal impact on the MOS transistor in the charge readout region 20.

However, the shallow trench electrode E12 is not limited to the arrangement described above. In another embodiment, the shallow trench electrode E12 extends along both the sidewall of the shallow trench adjacent to the light sensing region 10 and the bottom surface thereof. Thus, the shallow trench electrode E12 has, for example, an L-shaped longitudinal cross-section, and the linear isolation layer 105 on the bottom surface of the shallow trench is covered by the shallow trench electrode E12. A side surface of an upper portion of the shallow trench electrode E12 facing the charge readout region 20 (e.g., a vertical leg of the L-shaped shallow trench electrode E12) is covered by the first dielectric filler layer 108, and a lower portion thereof (e.g., a horizontal leg of the L-shaped shallow trench electrode E12) is isolated from the charge readout region 20 only by the linear isolation layer 105. With this arrangement, as the well region of the MOS transistor, which is intended to experience a potential change, is located essentially in an upper portion of the charge readout region 20 above a top surface of the lower portion of the shallow trench electrode E12, a voltage applied to the shallow trench electrode E12 will also have a minimal impact on the MOS transistor in the charge readout region 20 because of a large thickness of the isolation dielectric material between the upper portion of the shallow trench electrode E12 and the charge readout region 20.

The deep trench electrodes E11 in the DTI structures DTI may laterally surround the pixel areas PA and extend in the thickness direction of the substrate 100. For each pixel area PA, compared to deep trench electrodes E11 surrounding the light sensing region 10, deep trench electrodes E11 surrounding the charge readout region 20 may be offset away from the charge readout region 20, in order not to adversely affect the MOS transistor in the charge readout region 20.

FIG. 3 shows a plan view, for example, taken at the same height as the shallow trench electrodes E11, in which pixel areas PA are indicated by dashed boxes. The cross-sectional view of FIG. 2 is, for example, taken along line AA′ of FIG. 3. Referring to FIGS. 2 and 3, as an example, in the plurality of pixel areas PA of the substrate 100, the charge readout regions 20 of two different pixel areas PA may be adjacent to each other and sandwich a DTI structure DTI, in which, the deep trench electrode E11 is offset away from the two charge readout regions 20. For example, the deep trench electrode E11 may extend from a level below the shallow trenches to a level around the bottom surfaces of the shallow trenches. In other words, the top surface of the deep trench electrode E11 may be below, flush with or above the bottom surfaces of the shallow trenches, but lower than the top surfaces of the shallow trenches. As shown in FIG. 2, in the DTI structure DTI between the two charge readout regions 20, the first dielectric filler layer 108 may reside on top of the deep trench electrode E11.

Referring to FIGS. 2 and 3, in the plurality of pixel areas, the light sensing regions 10 of two different pixel areas PA may be adjacent to each other and sandwich a DTI structure DTI, in which the deep trench electrode E11 may extend from a level below the shallow trenches to a level higher than at least part of the shallow trench electrodes E12 in the shallow trenches, for example, to the same level as the top surfaces of the shallow trench electrodes E12 in the shallow trenches. This deep trench electrode E11 may be isolated by the linear isolation layer 105 from the sandwiching light sensing regions 10.

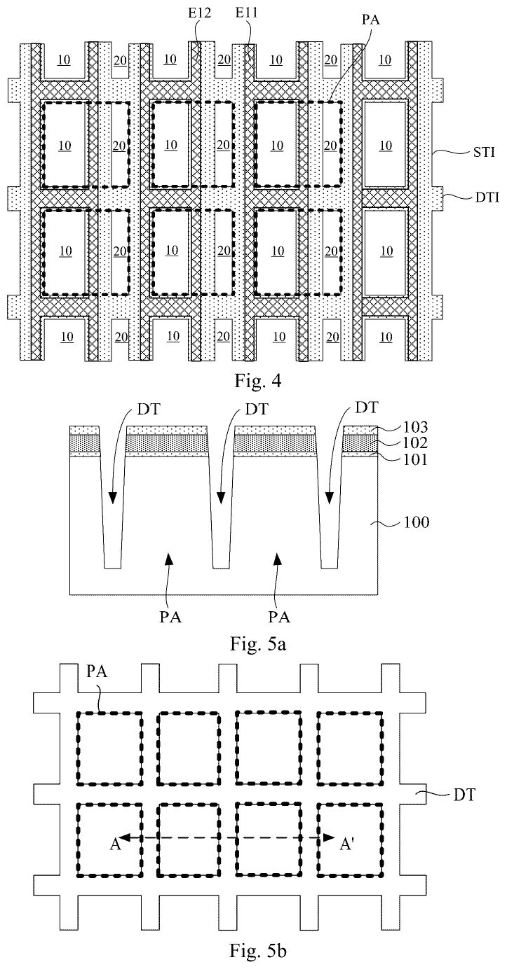

FIG. 4 shows another plan view, for example, also taken at the same height as the shallow trench electrodes E11. Referring to FIG. 4, in another embodiment, in the plurality of pixel areas PA of the substrate 100, the light sensing region 10 of one pixel area PA and the charge readout region 20 of another pixel area PA may be adjacent to each other and sandwich a DTI structure DTI, in which the deep trench electrode E11 may be closer to the light sensing region 10, like the shallow trench electrodes E12 between the light sensing regions 10 and the charge readout regions 20. Specifically, the deep trench electrode E11 may extend from a level below the shallow trenches to a level higher than at least part of the shallow trench electrodes E12 in the shallow trenches, while the deep trench electrode E11 is offset away from the charge readout region 20.

In the VPS, the deep trench electrodes E11 and the shallow trench electrodes E12 serve for generation of electric fields at the boundaries of the deep and shallow trenches and the substrate 100. The deep trench electrodes E11 and the shallow trench electrodes E12 may extend into non-pixel areas (e.g., peripheral circuit areas) of the substrate 100 and provide respective electrode terminals. As shown in FIGS. 3 and 4, the shallow trench electrodes E12 may laterally extend in the shallow trenches and be electrically connected to the deep trench electrodes E11 in the deep trenches. Accordingly, a voltage may be applied through external connection terminals of either the deep trench electrodes E11 or the shallow trench electrodes E12.

The VPS proposed herein offers the benefits as follows. The DTI structures DTI defines a plurality of pixel areas PA in the substrate 100, the DTI structures DTI may extend through substrates 100 to effectively isolate the pixel areas PA from one another, contributing to reduced pixel-to-pixel crosstalk and resulting in enhanced quantum efficiency. As coupling electrodes, the deep trench electrodes E11 and the shallow trench electrodes E12 may be coupled to other electrodes in the sensor (e.g., the substrate electrodes E2) to enhance performance of the sensor. For example, in a light sensing operation, a positive bias voltage may be applied between the pixel areas PA and the deep and shallow trench electrodes E11 and E12 to raise potential barriers at the boundaries of the DTI and STI structures DTI and STI and the substrate 100, reducing the probability of photoelectrons being captured at the boundaries during these operations, contributing to enhanced quantum efficiency and improved imaging quality. In addition, in each STI structure STI, the shallow trench electrode E12 may be offset toward the light sensing region 10 on one side of the STI structures STI to allow a voltage applied to the shallow trench electrode E12 to exert a greater impact on a potential in the light sensing region 10 than on a potential in the charge readout region 20. This can reduce loss of photoelectrons while less affecting the MOS transistor in the charge readout region 20.

Embodiments of the present invention also provide a method of manufacture of a VPS. The VPS described above can be obtained according to this method. The method is described in greater detail below with reference to FIGS. 5a to 19.

First of all, referring to FIG. 5a, a substrate 100 is provided, which is, for example, a silicon substrate. The substrate 100 is of a first doping type, which is, for example, p-type.

Next, DTI structures DTI and STI structures STI are formed in the substrate 100.

Specifically, as shown in FIG. 5a, a stack of a pad oxide layer 101 (e.g., a silicon oxide layer) and a hard mask layer is formed on a surface of the substrate 100. For example, the hard mask layer includes a first hard mask layer 102 and a second hard mask layer 103 on the first hard mask layer 102. The first hard mask layer 102 includes, for example, silicon nitride, and the second hard mask layer 103 includes, for example, silicon oxide. The hard mask layer, the pad oxide layer 101 and the substrate 100 are then etched, forming deep trenches DT extending from a top surface of the hard mask layer into the substrate 100. The deep trenches DT may have a depth greater than 1.5 μm. FIG. 5b shows a plan view of the substrate 100 after the deep trenches DT are formed. FIG. 5a is a cross-sectional view, for example, taken along line AA′ of FIG. 5b. Referring to FIG. 5b, the deep trenches DT may extend in a plane of the substrate 100, partitioning the substrate 100 into a plurality of pixel areas PA. The deep trenches DT surround the pixel areas PA.

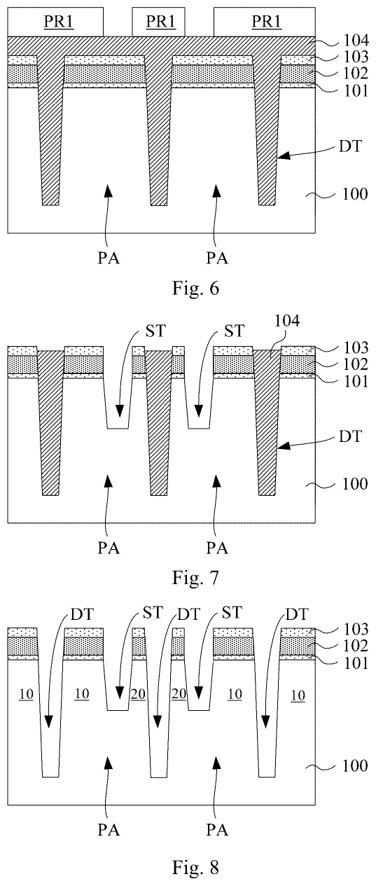

As shown in FIG. 6, a first sacrificial layer 104 may be formed in the deep trenches DT and a top surface of the substrate 100, and then a first photoresist layer PR1 on a top surface of the first sacrificial layer 104. A pattern of shallow trenches may be defined in the first photoresist layer PR1 by photolithography. For example, the first sacrificial layer 104 may be a bottom anti-reflective coating (BARC). As shown in FIG. 7, the sacrificial layer 104 is etched with the first photoresist layer PR1 serving as a mask, and the hard mask layer, the pad oxide layer 101 and the substrate 100 are then etched with the sacrificial layer 104 serving as a stop layer, forming shallow trenches ST extending from the top surface of the hard mask layer into the substrate 100. The shallow trenches ST may have a depth, for example, in the range of about 150 nm to 450 nm. In the etching process, the first photoresist layer PR1 and the sacrificial layer 104 may be partially removed. Preferably, after the etching process is completed, the sacrificial layer 104 remaining in the deep trenches DT has a top surface higher than a top surface of the first hard mask layer 102, in order to provide protection to sidewalls of the deep trenches DT. As shown in FIG. 8, after the shallow trenches ST are formed, the remainder of the sacrificial layer 104, emptying the deep trenches DT and the shallow trenches ST. The shallow trenches ST are formed in the respective pixel areas PA. In each pixel area PA, the shallow trench ST extends laterally and communicates with adjacent deep trenches DT, partitioning the pixel area PA into a light sensing region 10 and a charge readout region 20 on opposite sides of the shallow trench ST. In this embodiment, the light sensing regions 10 and the charge readout regions 20 are arranged, for example, as shown in FIG. 3. FIG. 8 is a cross-sectional view, for example, taken along line AA′ of FIG. 3.

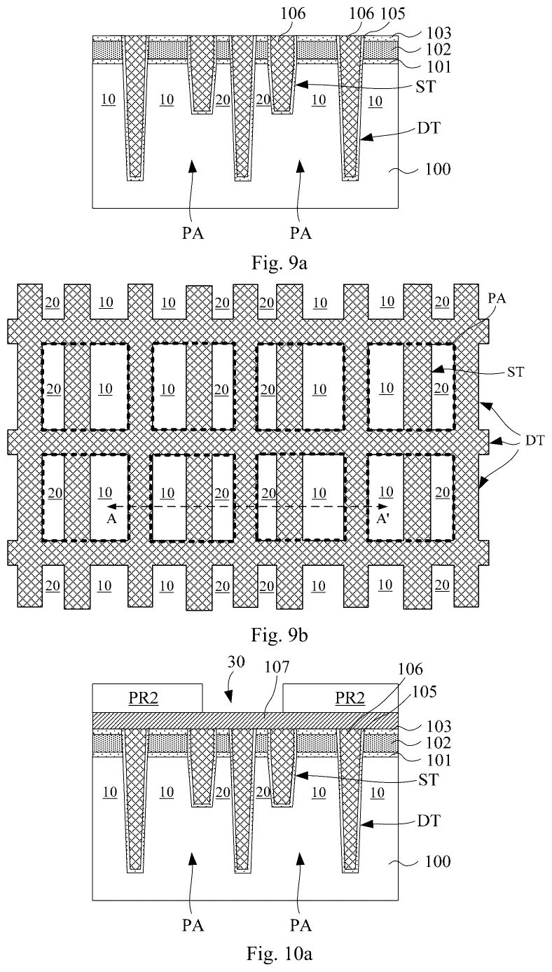

As shown in FIG. 9a, a linear isolation layer 105 is formed on inner surfaces of the deep trenches DT and the shallow trenches ST. For example, the linear isolation layer 105 includes silicon oxide and has a thickness of, for example, about 50 Å to 200 Å. An annealing process may follow. A conductive material is then deposited to fill the deep trenches DT and the shallow trenches ST and cover the hard mask layer, and a top surface of the conductive material is then planarized (e.g., by chemical mechanical polishing (CMP)), with the remainder of the conductive material in the deep trenches DT and the shallow trenches ST forming a trench electrode layer 106. Optionally, the trench electrode layer 106 may include one, or a combination of two or more, of tungsten, tungsten silicide, titanium, titanium nitride and doped polysilicon. In this embodiment, the trench electrode layer 106 is, for example, doped polysilicon. An annealing process may follow the deposition to recrystallize the doped polysilicon to an appropriate grain size. FIG. 9b is a plan view, for example, taken at the same height as the shallow trenches ST, in which the linear isolation layer 105 is not shown. FIG. 9a shows a cross-sectional view, for example, taken along line AA′ of FIG. 9b. As shown in FIG. 9b, after the trench electrode layer 106 is formed, in this embodiment, the trench electrode layer 106 in the deep trenches DT and the shallow trenches ST is continuous at boundaries of the pixel areas PA. However, the present invention is not so limited, because in other embodiments, the trench electrode layer 106 may also be formed separately in the deep trenches DT and the shallow trenches ST, and in these cases, it may not be continuous at the boundaries of the pixel areas PA.

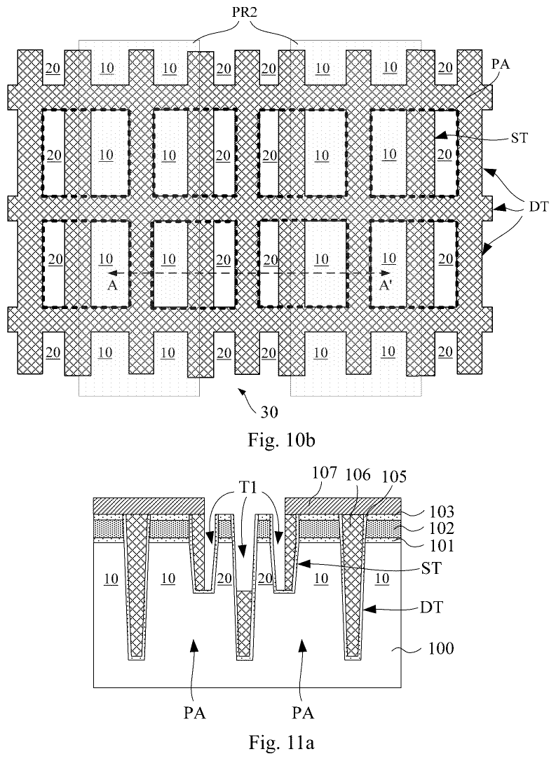

As shown in FIG. 10a, a mask pattern is defined in the substrate 100 for etching the trench electrode layer 106. For example, a third hard mask layer 107 is first formed over the first surface 100a. The third hard mask layer 107 may be a bottom anti-reflective coating (BARC), or made of silicon nitride, silicon carbide or another suitable material. Subsequently, a second photoresist layer PR2 is formed on a surface of the third hard mask layer 107, and openings 30 are formed in the second photoresist layer PR2 by photolithography, the openings 30 expose portions of the trench electrode layer 106 to be etched.

FIG. 10b shows the substrate 100 and the second photoresist layer PR2 with the openings 30 on the substrate 100. FIG. 10a is a cross-sectional view, for example, taken along line AA′ of FIG. 10b. Referring to FIG. 10b, in order to reduce the influence of trench electrodes to be formed around the charge readout regions 20 on potentials in well regions in MOS transistors to be formed in the charge readout regions 20, the openings 30 in the second photoresist layer PR2 expose top surface portions of the trench electrode layer 106 in the shallow trenches ST and at least part of top surface portions of the trench electrode layer 106 in the deep trenches DT surrounding the charge readout regions 20. In this embodiment, the plurality of pixel areas PA in the substrate 100 are grouped in such a manner that, in each adjacent pair of pixel areas PA, the two charge readout regions 20 are adjacent to each other and sandwich a deep trench DT between them. Since there is no light sensing region 10 for collecting photoelectrons on either side of the deep trench DT, it is not necessary to form a trench electrode in this deep trench DT. Accordingly, top surface of the trench electrode layer 106 in the deep trench DT is entirely exposed. On the other hand, some of the deep trenches DT are sandwiched by the light sensing regions 10 of the pixel areas PA on opposite sides thereof, and forming trench electrodes in these deep trenches DT will not have an impact on the MOS transistors to be formed in the charge readout regions 20. Therefore, these deep trenches DT are not exposed in the openings 30.

However, the present invention is not so limited, because depending on the arrangement of the pixel areas, a different pattern than shown in FIG. 10b may be defined in the second photoresist layer PR2. For example, referring to FIG. 4, in an alternative embodiment, the plurality of pixel areas PA in the substrate 100 are grouped in such a manner that, in each adjacent pair of pixel areas PA, the charge readout region 20 of one pixel area PA and the light sensing region 10 of the other pixel area PA are adjacent to each other and sandwich a deep trench DT between them. In this case, since the deep trench DT is sandwiched by the charge readout region 20 and the light sensing region 10, in order to reduce the risk of leakage of the light sensing region 10 as a consequence of forming a trench electrode in the deep trench DT, the second photoresist layer PR2 covering a portion of the trench electrode layer 106 in the deep trench DT, which faces the light sensing region 10, may be retained and not etched away. At the same time, in order to avoid the trench electrode to be formed in the deep trench DT from adversely affecting a potential in a well region to be formed in the charge readout region 20, the remaining top surface portion of the trench electrode layer 106 in the deep trench DT adjacent to the charge readout region 20 may be exposed in an opening 30.

As shown in FIG. 11a, the third hard mask layer 107 is first etched with the second photoresist layer PR2 serving as a mask and the trench electrode layer 106 is then etched back in turn with the etched third hard mask layer 107 serving as a mask, forming first gaps T1 in the deep trenches DT and the shallow trenches ST that surround the charge readout regions 20. In this embodiment, the first gaps T1 expose at least portions of the linear isolation layer 105 in the deep trenches DT and the shallow trenches ST that surround the charge readout regions 20, which cover side surfaces of the charge readout regions 20.

For example, the first gaps T1 surround the charge readout regions 20. As shown in FIG. 11a, in each shallow trench ST, a lateral portion of the trench electrode layer 106 is etched away, resulting in a first gap T1 exposing a side surface of the trench electrode layer 106 remaining in the shallow trench ST. In each deep trench DT sandwiched by charge readout regions 20, an upper portion of the trench electrode layer 106 is completely etched away, resulting in a first gap T1 on top of the remaining trench electrode layer 106. In each deep trench DT sandwiched by the charge readout region 20 of one pixel area PA and the light sensing region 10 of another pixel area PA, a lateral portion of the trench electrode layer 106 adjacent to the charge readout region 20 is etched away in the etch-back process, resulting in a first gap T1 exposing a side surface of the remaining trench electrode layer 106 that is adjacent to the charge readout region 20.

Referring to FIG. 11a, the first gaps T1 have a depth, which is, for example, greater than or equal to a thickness of the trench electrode layer 106 in the shallow trenches ST before it is etched, in order to partially expose portions of the linear isolation layer 105 covering bottom surfaces of the shallow trenches ST in the resulting first gaps T1. However, the present invention is not so limited. For example, referring to FIG. 11b, in an alternative embodiment, the depth of the first gaps T1 may also be less than the thickness of the trench electrode layer 106 in the shallow trenches ST before it is etched. As a result, the trench electrode layer 106 residing on the bottom of the shallow trenches ST is retained. In this way, a voltage applied to the subsequently-formed shallow trench electrodes will have a greater impact on portions thereof around the bottom surfaces of the shallow trenches ST. Accordingly, through applying an appropriate voltage, the risk of photoelectrons being captured around the bottom surfaces of the shallow trenches ST can be lowered.

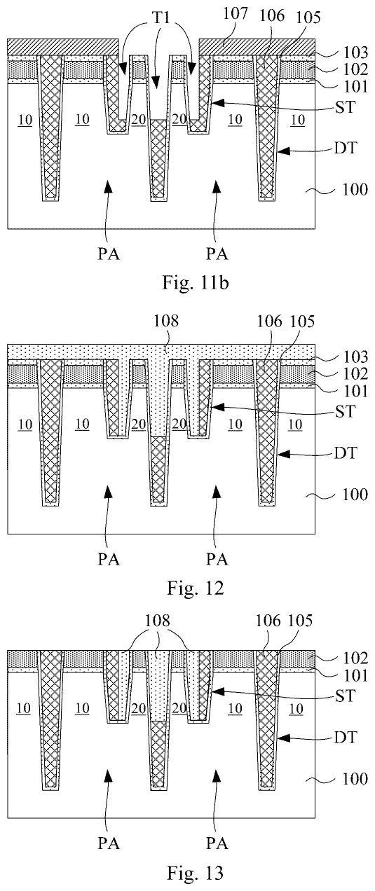

The third hard mask layer 107 is removed from the structure of FIG. 11a, and a first dielectric filler layer 108 is then formed, which fills the first gaps T1 and resides above the second hard mask layer 103, the deep trenches DT and the shallow trenches ST, as shown in FIG. 12. For example, the first dielectric filler layer 108 is silicon oxide. After that, as shown in FIG. 13, a top surface of the first dielectric filler layer 108 is planarized (e.g., by CMP), exposing the top surface of the first hard mask layer 102, the remainder of the first dielectric filler layer 108 fills the first gaps T1.

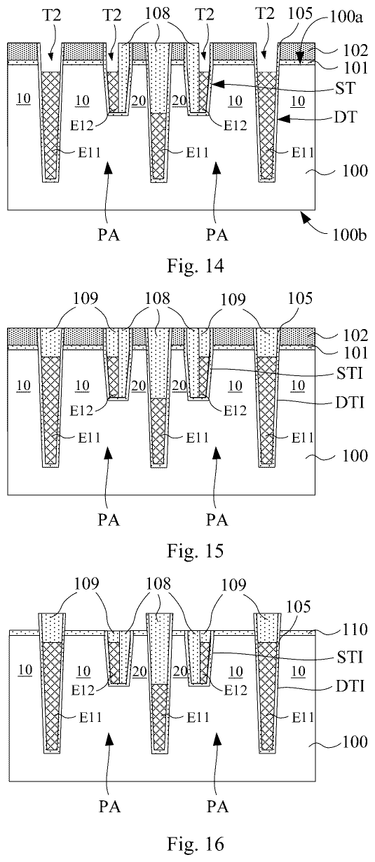

As shown in FIG. 14, the trench electrode layer 106 is again etched back to lower the top surface of the trench electrode layer 106 below the top surface of the substrate 100. As a result of this etch-back process, second gaps T2 are formed in upper portions of the shallow trenches ST and the deep trenches DT, and the remaining trench electrode layer 106 forms deep trench electrodes E11 in the deep trenches ST and shallow trench electrodes E12 in the shallow trenches ST. Top surfaces of the deep trench electrodes E11 and the shallow trench electrodes E12 are not higher than the top surface of the substrate 100, to enable isolation of gate structures to be subsequently formed on the substrate 100. In this embodiment, the deep trench electrodes E11 are connected to the shallow trench electrodes E12. Portions of the trench electrode layer 106 in non-pixel areas (e.g., peripheral circuit areas) may survive from the second etch-back process and be subsequently processed into electrode terminals for the deep trench electrodes E11 and the shallow trench electrodes E12 in the non-pixel areas.

As shown in FIG. 15, a second dielectric filler layer 109 is formed in the second gaps T2. At this point, DTI structures DTI and STI structures STI are formed in the deep trenches DT and the shallow trenches ST in the substrate 100, respectively. Each DTI structure DTI includes a respective one of the deep trenches DT, a respective one of the deep trench electrodes E11 in the respective deep trench DT and a DTI dielectric material filled in the deep trench DT so as to isolate the deep trench electrode E11 from the substrate 100. The DTI dielectric material includes a portion of the linear isolation layer 105, a portion of the first dielectric filler layer 108 and a portion of the second dielectric filler layer 109. Each STI structure STI includes a respective one of the shallow trenches ST, a respective one of the shallow trench electrodes E12 in the respective shallow trench ST and an STI dielectric material filled in the shallow trench DT so as to isolate the shallow trench electrode E12 from the substrate 100. The STI dielectric material includes a portion of the linear isolation layer 105, a portion of the first dielectric filler layer 108 and a portion of the second dielectric filler layer 109.

Gate structures are then formed on the substrate 100, and source regions and drain regions are formed in the charge readout regions 20 on opposite sides of the gate structures, as detailed below.

As shown in FIG. 16, the STI dielectric material is etched back so that a top surface thereof remaining in the shallow trenches ST is below a top surface of the DTI dielectric material but not the top surface of the substrate 100 (e.g., higher than a top surface of the pad oxide layer 101). This is followed by removing the first hard mask layer 102 and the pad oxide layer 101 from the substrate 100 and then forming a gate dielectric layer 110 on the exposed surface of the substrate 100. After the first hard mask layer 102 is removed and before the gate dielectric layer 110 is formed, well regions (e.g., p-well regions, not shown) may be formed in the charge readout regions 20 by ion implantation.

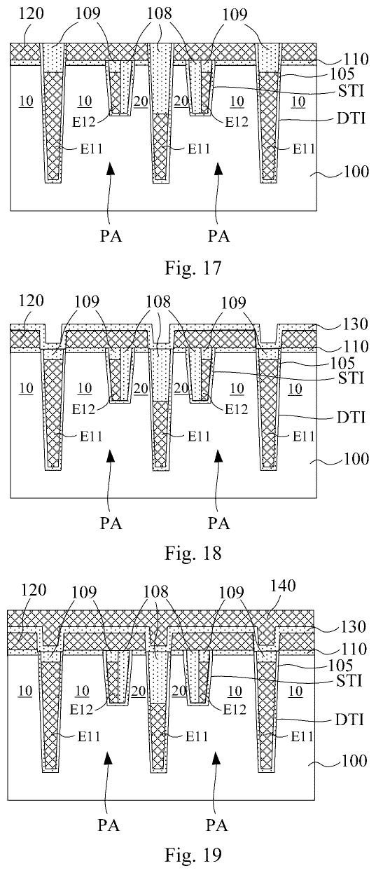

As shown in FIG. 17, a floating gate material layer 120 is formed on the pixel areas PA of the substrate 100 so that portions of the floating gate material layer 120 on the respective pixel areas PA are surrounded by the DTI structures DTI.

As shown in FIG. 18, the trench isolation structure in the deep trenches DT are etched back, forming grooves in the floating gate material layer 120 between adjacent pixel areas PA. An inter-gate dielectric layer 130 is then formed over a surface of the floating gate material layer 120 and inner surfaces of the grooves. The inter-gate dielectric layer 130 is, for example, an oxide-nitride-oxide (ONO) stack. After that, as shown in FIG. 19, doped polysilicon is deposited onto the substrate 100 into a control gate material layer 140.

Further, referring to FIG. 2, the method may include perform, on the structure of FIG. 19, the processes as detailed below.

Locations where control gates CG are to be formed are defined by photolithography. The control gate material layer 140, as well as the inter-gate dielectric layer 130 and the floating gate material layer 120 under the control gate material layer 140, is etched, forming floating gates FG and control gates CG on the respective pixel areas PA. An LDD implantation process may be carried out on those of the charge readout regions 20 that are on opposite sides of the control gates CG, and spacers are then formed on side surfaces of the control gates CG, the inter-gate dielectric layer 130 and the floating gates FG, thereby forming the gate structures. The control gates CG on the pixel areas PA may be connected to form at least one word line.

A source/drain ion implantation process is then carried out on the charge readout regions 20 on opposite sides of the gate structures, forming source and drain regions. An interlayer dielectric layer may be then formed, which covers the gate structures and the substrate 100, and contact plugs extending through the interlayer dielectric layer and connecting the source and drain regions. After that, source line(s) (not shown) connecting the source regions and bit line(s) (not shown) connecting the drain regions may be further on the interlayer dielectric layer.

Afterwards, the substrate 100 may be thinned from the side away from the gate structures, exposing the linear isolation layer 105 or deep trench electrodes E11 in the DTI structures DTI. As a result, the DTI structures DTI extend through the substrate 100 and completely isolate the pixel areas PA surrounded by them from one another, contributing to reduced crosstalk. Additionally, substrate electrodes E2 may be formed on the thinned surface of the substrate 100, in order to allow a voltage to be applied to the substrate 100 in the pixel areas PA through the respective substrate electrodes E2. Furthermore, a high-k material layer 150 may be formed on the second surface 100b and further disposed between the substrate electrodes E2 and the DTI structures DTI, in order to achieve improved photoelectric conversion efficiency.

The VPS obtained according to the above described method is as shown in FIGS. 2 and 3. The deep trench electrodes E11 are formed in the respective DTI structures DTI, and the shallow trench electrodes E12 in the respective STI structures STI. In the STI structures STI, thicknesses of portions of the STI dielectric material respectively adjacent the light sensing regions 10 and the charge readout regions 20 may be configured so that, in each pixel area PA, the shallow trench electrode E12 is offset toward the light sensing region 10 beside of the STI structure STI. This arrangement enables coupled use of the deep and shallow trench electrodes E11 and E12 and the substrate electrodes E2 in a light sensing operation—the shallow trench electrodes E12 exert a greater impact on potentials in the light sensing regions 10 than on potentials in the charge readout regions 20. This can reduce both the likelihood of photoelectrons in the light sensing regions 10 being captured at the boundaries of the STI structures STI and the substrate 100 and the influence on potentials in the well regions of the MOS transistors in the charge readout regions 20.

Embodiments of the present invention also relate to a method of operation of the VPS as discussed above. The method of operation includes a light sensing operation and a photoelectron readout operation. In the light sensing operation, a positive voltage (e.g., 0 V to 5 V) is applied to the gate structures, a first negative voltage (e.g., −3 V to 0 V) to the substrate 100 and a second negative voltage lower than the first negative voltage (e.g., −6 V to −1 V) to the deep and shallow trench electrodes E11 and E12, causing photoelectrons to gather at top surfaces of the light sensing regions 10. In the photoelectron readout operation, with the first and second negative voltages being maintained and corresponding voltages being applied respectively to the gate structures, the source regions and the drain regions, threshold voltage changes of the MOS transistors before and after the light sensing operation are detected for readout of the photoelectrons.

The method of operation may further include a reset operation, in which, a first reset voltage is applied to the substrate 100, a second reset voltage higher than the first reset voltage to the deep trench electrodes E11 and the shallow trench electrode E12 and a third reset voltage lower than or equal to the first reset voltage to the gate structures, causing scattering of the photoelectrons back into the substrate 100. In the light sensing and reset operations, the source and drain regions in the charge readout regions 20 are grounded, for example.

This method can provide photoelectric conversion, in which a negative bias voltage may be applied between the deep and shallow trench electrodes E11 and E12 and the substrate 100 to raise a potential barrier at the boundaries of the DTI and STI structures DTI and STI and the substrate 100, thereby lowering the probability of photoelectrons being captured at the boundaries, reducing loss of photoelectrons and contributing to enhanced quantum efficiency in the light sensing operation. In addition, a positive bias voltage may be applied between the deep and shallow trench electrodes E11 and E12 and the substrate 100 to facilitate release of electrons trapped at the boundaries of the DTI and STI structures DTI and STI and the substrate 100, contributing to mitigated background noise.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

1. A vertically-charge-transferring pixel sensor (VPS), comprising:
a substrate of a first doping type;
deep trench isolation (DTI) structures each comprising a deep trench extending through the substrate, a deep trench electrode formed in the deep trench and a DTI dielectric material filled in the deep trench so as to isolate the deep trench electrode from the substrate, the DTI structures partitioning the substrate into a plurality of pixel areas;
shallow trench isolation (STI) structures each comprising a shallow trench extending from a surface of the substrate into the substrate, a shallow trench electrode formed in the shallow trench and an STI dielectric material filled in the shallow trench so as to isolate the shallow trench electrode from the substrate, the STI structures traversing the respective pixel areas and thereby partitioning the pixel areas into light sensing regions and charge readout regions on opposite sides of the STI structures;
gate structures formed on surfaces of the respective pixel areas so as to extend from the respective light sensing regions to the respective charge readout regions, the gate structures in the light sensing regions constituting, together with the substrate, MOS capacitors for collecting photo-charge; and
source regions and drain regions formed in the charge readout regions on opposite sides of the gate structures so as to constitute, together with the gate structures in the charge readout regions, MOS transistors for readout of the photo-charge.

2. The VPS of claim 1, wherein the shallow trench electrodes in the STI structures are offset toward the light sensing regions on one side of the STI structures.

3. The VPS of claim 2, wherein the shallow trench electrodes extend along sidewalls of the shallow trenches adjacent to the light sensing regions, or wherein the shallow trench electrodes extend along both the sidewalls of the shallow trenches adjacent to the light sensing regions and bottom surfaces of the shallow trenches.

4. The VPS of claim 1, wherein the deep trench electrodes in the DTI structures laterally surround the pixel areas, wherein for each pixel area, compared to deep trench electrodes surrounding the light sensing region, deep trench electrodes surrounding the charge readout region are offset away from the charge readout region.

5. The VPS of claim 4, wherein in the plurality of pixel areas, the charge readout regions of two different ones of the pixel areas are adjacent to each other and sandwich one of the DTI structures, in which the deep trench electrode extends from a level below the shallow trenches to a level around bottom surfaces of the shallow trenches.

6. The VPS of claim 4, wherein in the plurality of pixel areas, the light sensing regions of two different ones of the pixel areas are adjacent to each other and sandwich one of the DTI structures, in which the deep trench electrode extends from a level below the shallow trenches to a level higher than at least part of the shallow trench electrodes in the shallow trenches.

7. The VPS of claim 4, wherein in the plurality of pixel areas, the light sensing region of one of the pixel areas and the charge readout region of a different one of the pixel areas are adjacent to each other and sandwich one of the DTI structures, in which the deep trench electrode extends from a level below the shallow trenches to a level higher than at least part of the shallow trench electrodes in the shallow trenches and is offset away from the charge readout region.

8. The VPS of claim 1, wherein the DTI dielectric material and the STI dielectric material comprise:
a linear isolation layer formed on inner surfaces of the deep trenches and the shallow trenches, wherein the deep trench electrodes are formed on part of surface portions of the linear isolation layer in the deep trenches, and the shallow trench electrodes are formed on part of surface portions of the linear isolation layer in the shallow trenches;
a first dielectric filler layer, which is formed on the rest of the surface portions of the linear isolation layer in the deep trenches so as to be contiguous with the deep trench electrodes, and on the rest of the surface portions of the linear isolation layer in the shallow trenches so as to be contiguous with the shallow trench electrodes, wherein the first dielectric filler layer and the linear isolation layer are stacked one on the other and both surround side surfaces of the charge readout regions, thereby isolating the charge readout regions from the deep trench electrodes and the shallow trench electrodes; and
a second dielectric filler layer formed on top surfaces of the shallow trench electrodes and top surfaces of the deep trench electrodes.

9. The VPS of claim 8, wherein over at least part of a depth of the shallow trenches, the shallow trench electrodes and the first dielectric filler layer are juxtaposed in a widthwise direction of the shallow trenches.

10. The VPS of claim 8, wherein the linear isolation layer formed on bottom surfaces of the shallow trenches are covered by the shallow trench electrodes, or wherein part of the linear isolation layer formed on the bottom surfaces of the shallow trenches are covered by the shallow trench electrodes, with the rest being covered by the first dielectric filler layer.

11. The VPS of claim 8, wherein in the plurality of pixel areas, the charge readout regions of two different ones of the pixel areas are adjacent to each other and sandwich one of the DTI structures, in which the first dielectric filler layer resides on a top of the corresponding deep trench electrode.

12. The VPS of claim 8, wherein the linear isolation layer has a thickness of 5 nm to 20 nm and wherein the first dielectric filler layer has a thickness of 10 nm to 50 nm.

13. The VPS of claim 1, wherein the shallow trench electrodes laterally extend in the shallow trenches and are electrically connected to the deep trench electrodes.

14. A method of manufacture of a vertically-charge-transferring pixel sensor (VPS), wherein the method of manufacture comprises:
providing a substrate of a first doping type;
forming deep trenches and shallow trenches extending from one side of the substrate into the substrate;
forming deep trench isolation (DTI) structures and shallow trench isolation (STI) structures in the substrate, each of the DTI structures comprising a respective one of the deep trenches, a deep trench electrode formed in the deep trench and a DTI dielectric material filled in the deep trench so as to isolate the deep trench electrode from the substrate, the DTI structures partitioning the substrate into a plurality of pixel areas, each of the STI structures comprising a respective one of the shallow trenches, a shallow trench electrode formed in the shallow trench and an STI dielectric material filled in the shallow trench so as to isolate the shallow trench electrode from the substrate, the STI structures traversing the respective pixel areas and thereby partitioning the pixel areas into light sensing regions and charge readout regions on opposite sides of the STI structures; and
forming gate structures on surfaces of the respective pixel areas and source regions and drain regions in the charge readout regions on opposite sides of the gate structures, the gate structures extending from the respective light sensing regions to the respective charge readout regions, the gate structures in the light sensing regions constituting, together with the substrate, MOS capacitors for collecting photo-charge, the gate structures in the charge readout regions constituting, together with the source regions and the drain regions, MOS transistors for readout of the photo-charge.

15. The method of manufacture of claim 14, wherein forming the DTI structures and the STI structures in the substrate comprises:
forming a linear isolation layer on inner surfaces of the deep trenches and the shallow trenches;
filling the deep trenches and the shallow trenches with a trench electrode layer;
etching back the trench electrode layer to form first gaps in the deep trenches and the shallow trenches surrounding the charge readout regions, which expose at least part of the linear isolation layer in the deep trenches and the shallow trenches, which covers side surfaces of the charge readout regions;
forming a first dielectric filler layer in the first gaps;
again etching back the trench electrode layer to lower a top surface of the trench electrode layer below a top surface of the substrate and forming second gaps in upper portions of the deep trenches and the shallow trenches, with the remainder of the trench electrode layer forming the deep trench electrodes in the deep trenches and the shallow trench electrodes in the shallow trenches; and
forming a second dielectric filler layer in the second gaps, thereby forming the DTI structures corresponding to the respective deep trenches and the STI structures corresponding to the respective shallow trenches in the substrate.

16. The method of manufacture of claim 15, wherein in the plurality of pixel areas, the charge readout regions of two different ones of the pixel areas are adjacent to each other and sandwich one of the deep trenches, in which one of the first gaps resides on a top of the remainder of the trench electrode layer.

17. The method of manufacture of claim 15, wherein in the plurality of pixel areas, the light sensing region of one of the pixel areas and the charge readout region of a different one of the pixel areas are adjacent to each other and sandwich one of the deep trenches, in which one of the first gaps exposes part of the side surface of the remainder of the trench electrode layer adjacent the charge readout region.

18. The method of manufacture of claim 15, wherein in the plurality of pixel areas, the first gaps further expose part of the linear isolation layer covering bottom surfaces of the shallow trenches.

19. A method of operation of the VPS of claim 1, comprising a light sensing operation and a photoelectron readout operation, wherein in the light sensing operation, a positive voltage is applied to the gate structures, a first negative voltage to the substrate and a second negative voltage lower than the first negative voltage to the deep and shallow trench electrodes, causing photoelectrons to gather at top surfaces of the light sensing regions, and wherein in the photoelectron readout operation, with the first negative voltage and the second negative voltage being maintained and corresponding voltages being applied respectively to the gate structures, the source regions and the drain regions, threshold voltage changes of the MOS transistors before and after the light sensing operation are detected for readout of the photoelectrons.

20. The method of operation of claim 19, further comprising a reset operation, in which a first reset voltage is applied to the substrate, a second reset voltage higher than the first reset voltage to the deep trench electrodes and the shallow trench electrodes and a third reset voltage lower than or equal to the first reset voltage to the gate structures, causing scattering of the photoelectrons back into the substrate.
